(19) United States
(12) Patent Application Publication
(10) Pub. No.: US 2024/0126161 A1
(43) Pub. Date: Apr. 18, 2024

(54) EXTREME ULTRAVIOLET (EUV) MASK AND MANUFACTURING METHOD THEREOF

(71) Applicant: Samsung Electronics Co., Ltd., Suwon-si (KR)

(72) Inventors: Sungwoo JANG, Suwon-si (KR); Sunpyo LEE, Suwon-si (KR); Euihan JUNG, Suwon-si (KR)

(73) Assignee: Samsung Electronics Co., Ltd., Suwon-si (KR)

(21) Appl. No.: 18/320,387

(22) Filed: May 19, 2023

(30) Foreign Application Priority Data
Oct. 18, 2022 (KR) 10-2022-0134447

(51) Int. Cl. G03F 1/24; G03F 7/20

(52) U.S. Cl. CPC G03F 1/24; G03F 7/20

(57) ABSTRACT

An extreme ultraviolet (EUV) mask may include a substrate having a rectangular shape, a reflective layer on the substrate and having a rectangular shape smaller than the rectangular shape of the substrate, and an absorber layer on the reflective layer. The absorber layer may have a same shape as the rectangular shape of the reflective layer. The absorber layer may include a dummy hole pattern. The dummy hole pattern may be in a rectangular frame shape along an edge portion of the absorber layer and may include a plurality of dummy holes exposing the reflective layer.

### CROSS-REFERENCE TO RELATED APPLICATION

This application is based on and claims priority under 35 U.S.C. § 119 to Korean Patent Application No. 10-2022-0134447, filed on Oct. 18, 2022 in the Korean Intellectual Property Office, the disclosure of which is incorporated by reference herein in its entirety.

### BACKGROUND

Inventive concepts relate to a mask and/or a manufacturing method thereof, and particularly to, an extreme ultraviolet (EUV) mask used in a EUV exposure process and/or a manufacturing method thereof.

The sizes of patterns formed on semiconductor substrates may be getting smaller. In addition, the wavelengths of a light source used in a lithography process may be getting shorter. For example, in the lithography process, g-line (436 nm) and i-line (365 nm) were used in the past, and light in a deep ultraviolet (DUV) band and light in an extreme ultraviolet (EUV) band have been currently used. Because light in the EUV band is mostly absorbed in refractive optical materials, a EUV lithography may generally be performed using a reflective optical system rather than a refractive optical system.

### SUMMARY

Inventive concepts provide an extreme ultraviolet (EUV) mask with improved reliability and durability and/or a manufacturing method thereof.

In addition, features of inventive concepts are not limited to those described above, and other features and aspect may be understood by those of ordinary skill in the art from the description below.

According to an embodiment of inventive concepts, an extreme ultraviolet (EUV) mask may include a substrate having a rectangular shape; a reflective layer on the substrate and having a rectangular shape smaller than the rectangular shape of the substrate; and an absorber layer on the reflective layer. The absorber layer may have a same shape as the rectangular shape of the reflective layer, and the absorber layer may include a dummy hole pattern. The dummy hole pattern may be in a rectangular frame shape along an edge portion of the absorber layer. The dummy hole pattern may include a plurality of dummy holes. The plurality of dummy holes may expose the reflective layer.

According to an embodiment of inventive concepts, an extreme ultraviolet (EUV) mask may include a substrate having a rectangular shape; a reflective layer on the substrate and having a rectangular shape smaller than the rectangular shape of the substrate; and an absorber layer on the reflective layer. The absorber layer may have a same shape as the rectangular shape of the reflective layer. The absorber layer may include a transfer area and a dummy hole pattern. The transfer area may include an absorber pattern for a EUV process in a central portion of the absorber layer in a first direction. The absorber pattern may expose the reflection layer. The dummy hole pattern may be in a rectangular frame shape along an edge portion of the absorber layer. The dummy hole pattern may include a plurality of dummy holes. The plurality of dummy holes may expose the reflective layer.

According to an embodiment of inventive concepts, a manufacturing method of an extreme ultraviolet (EUV) mask may include sequentially forming a reflective layer, a capping layer, and an absorber layer on a substrate; and forming a plurality of dummy holes in the absorber layer. The plurality of dummy holes may expose the capping layer and may form a dummy hole pattern. The dummy hole pattern may have a rectangular frame shape along an edge portion of the absorber layer. The plurality of dummy holes may be formed through a photo process.

According to an embodiment of inventive concepts, a manufacturing method of an extreme ultraviolet (EUV) mask may include forming a blank mask; performing a mask defect avoidance (MDA) on the blank mask; and forming absorber patterns for a EUV process on an absorber layer of the blank mask. The absorber patterns may be formed using an electron beam exposure apparatus. The forming the blank mask may include sequentially forming a reflective layer, a capping layer, and an absorber layer on a substrate, and forming a plurality of dummy holes in the absorber layer. The plurality of dummy holes may expose the capping layer and form a dummy hole pattern. The dummy hole pattern may have a rectangular frame shape along an edge portion of the absorber layer. The plurality of dummy holes may be formed through a photo process.

### BRIEF DESCRIPTION OF THE DRAWINGS

Embodiments will be more clearly understood from the following detailed description taken in conjunction with the accompanying drawings in which:

FIG. 1 is a plan view of an extreme ultraviolet (EUV) mask according to an embodiment;

FIG. 2A is a plan view showing an enlarged portion A of the EUV mask of FIG. 1;

FIGS. 2B and 2C are respectively a scanning electron microscope (SEM) photograph and a plan view showing an enlarged portion B of FIG. 2A;

FIGS. 3A and 3B are cross-sectional views taken along line I-I′ of FIG. 1;

FIG. 3C is a cross-sectional view showing an enlarged portion C of FIG. 3A;

FIG. 4A is a plan view of a EUV mask according to an embodiment;

FIG. 4B is a plan view showing an enlarged portion D of the EUV mask of FIG. 4A;

FIG. 5A is a plan view of a EUV mask according to a comparative example;

FIG. 5B is a plan view showing an enlarged portion E of the EUV mask of FIG. 5A;

FIG. 6A is a plan view of a EUV mask according to an embodiment;

FIG. 6B is a cross-sectional view showing taken along line II-II′ of FIG. 6A;

FIG. 7 is a flowchart schematically illustrating a process of a manufacturing method of a EUV mask according to an embodiment;

FIGS. 8A to 8E are cross-sectional views of the EUV mask corresponding to operations of the manufacturing method of the EUV mask of FIG. 7; and

FIG. 9 is a flowchart schematically illustrating a process of a manufacturing method of a EUV mask according to an embodiment.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, embodiments of inventive concepts are described in detail with reference to the accompanying drawings. Like reference numerals in the drawings denote like elements, and their repetitive descriptions are omitted.

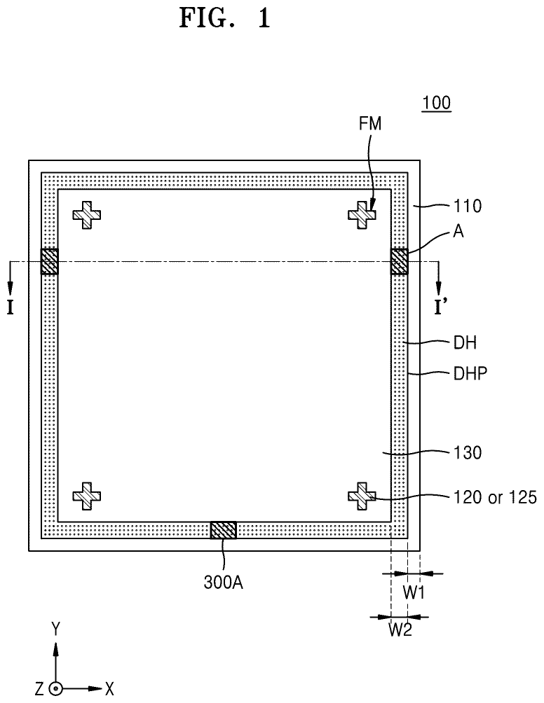

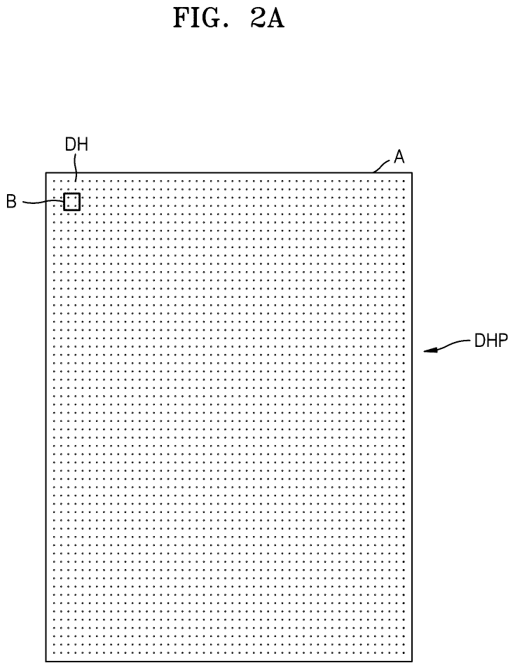

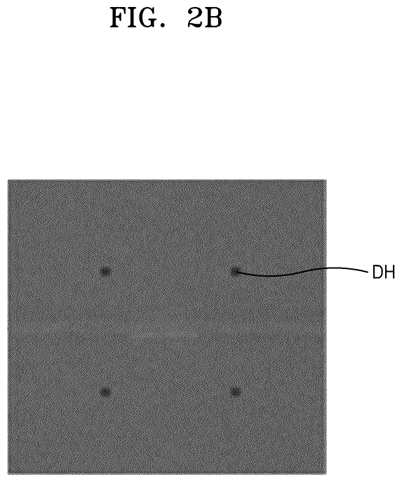

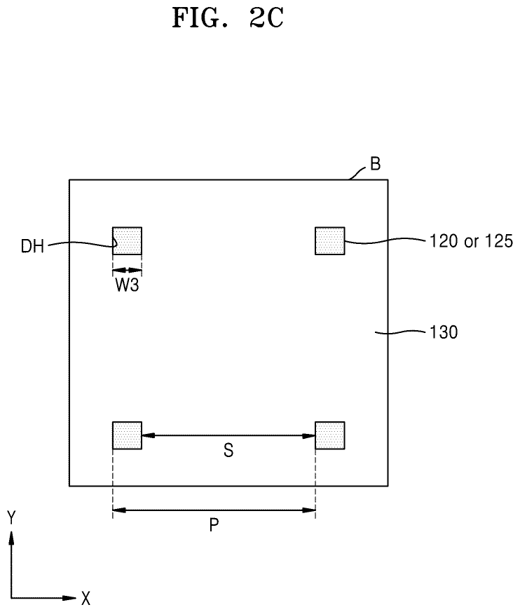

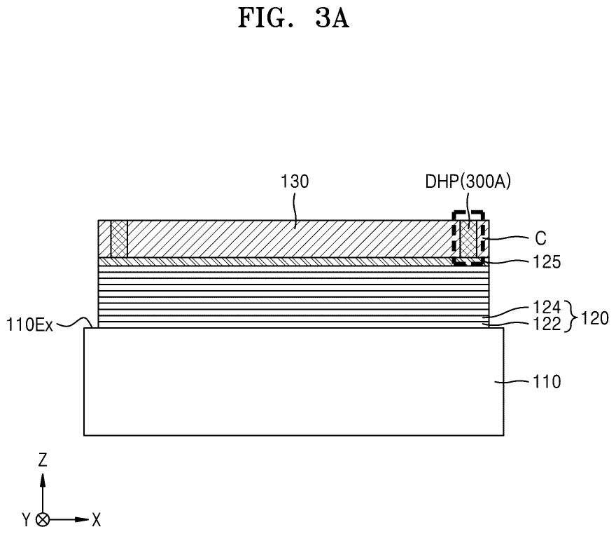

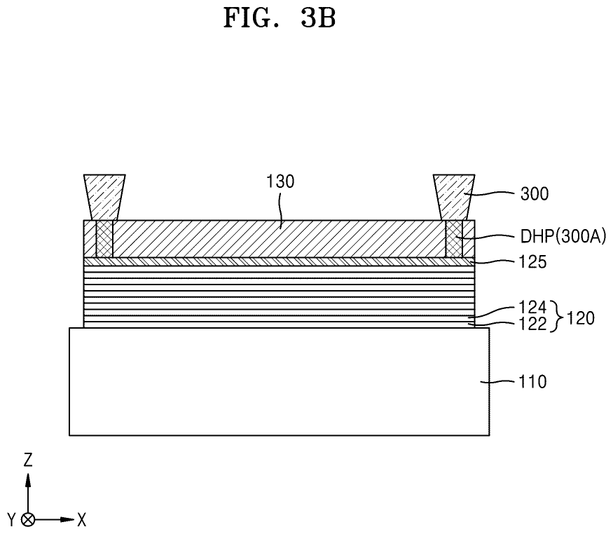

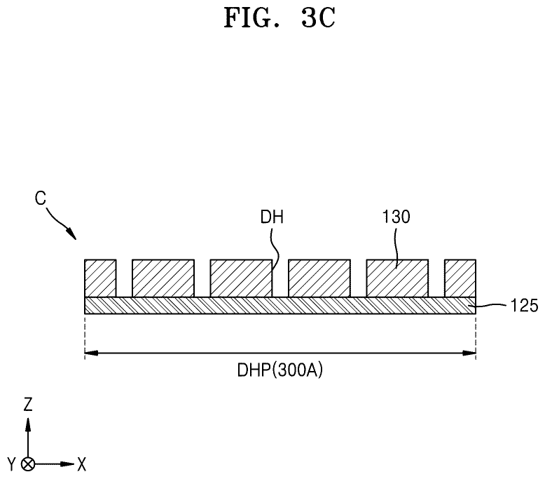

FIG. 1 is a plan view of an extreme ultraviolet (EUV) mask according to an embodiment. FIG. 2A is a plan view showing an enlarged portion A of the EUV mask of FIG. 1. FIGS. 2B and 2C are a scanning electron microscope (SEM) photograph and a plan view showing an enlarged portion B of FIG. 2A. FIGS. 3A and 3B are cross-sectional views taken along line I-I′of FIG. 1.

FIG. 3C is a cross-sectional view showing an enlarged portion C of FIG. 3A. FIG. 3B also illustrates a ground pin of an electron beam exposure apparatus.

Referring to FIGS. 1 to 3C, a EUV mask 100 of the present embodiment may include a substrate 110, a reflective layer 120, a capping layer 125, and an absorber layer 130. Each of the substrate 110, the reflective layer 120, the capping layer 125, and the absorber layer 130 may have a rectangular shape in a plan view, as may be seen from FIGS. 1 and 3A. In addition, the reflective layer 120, the capping layer 125, and the absorber layer 130 may have substantially the same size. However, the substrate 110 may have a larger size than the reflective layer 120, and accordingly, the substrate 110 may include an exposed portion 110Ex having an exposed upper surface in a rectangular frame shape at an outer portion thereof. A first width W1 of the exposed portion 110Ex may be, for example, equal to or greater than 1.0 mm. Here, the first width W1 may be defined in a direction perpendicular to a direction in which the exposed portion 110Ex extends. For example, in FIG. 1, in the case of the exposed portions 110Ex in the upper and lower sides extending in a first direction (X direction), the first width W1 may be defined in a second direction (Y direction), and in the case of the exposed portions 110Ex in the left and right sides extending in the second direction (Y direction), the first width W1 may be defined in the first direction (X direction).

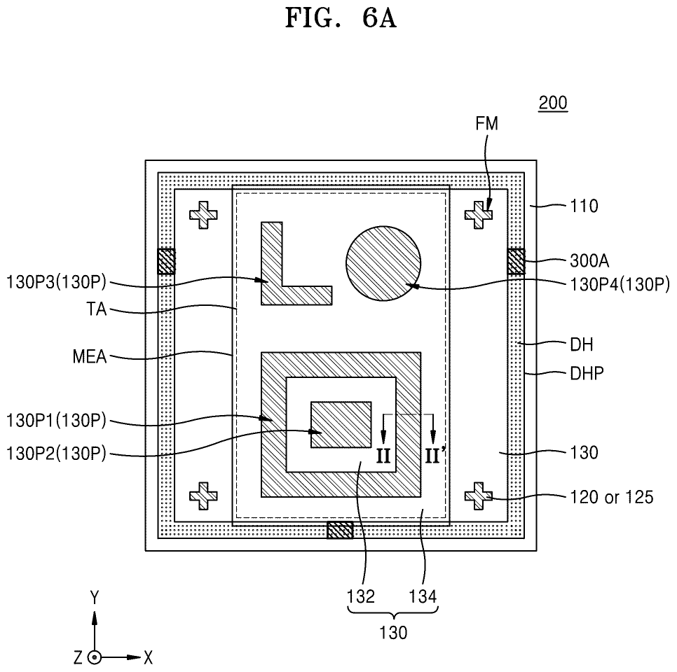

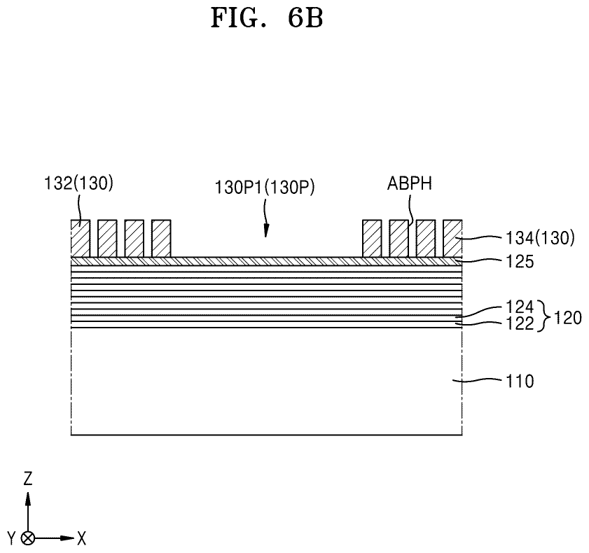

The substrate 110 may include a low thermal expansion material (LTEM). In other words, the substrate 110 may include a material having a low coefficient of thermal expansion (CTE). For example, the substrate 110 may include glass, silicon (Si), quartz, etc. However, the material of the substrate 110 is not limited to the above materials. The substrate 110 may include a transfer area (see TA of FIG. 6A) and a light blocking area outside the transfer area TA. Here, the transfer area TA may mean an area where patterns to be transferred on a wafer through an exposure process are disposed. Here, the patterns may refer to absorber patterns (see 132 and 134 of FIG. 6A) formed on the absorber layer 130. The transfer area TA and the light blocking area are described in more detail below with reference to FIGS. 6A and 6B.

The reflective layer 120 may be disposed on the substrate 110. The reflective layer 120 may reflect light incident on the reflective layer 120, for example, a EUV ray. The reflective layer 120 may include a Bragg reflector. In the EUV mask 100 of the present embodiment, the reflective layer 120 may have a multi-layer structure in which two material layers 122 and 124 are alternately stacked in several tens of layers. That is, the reflective layer 120 may include first material layers 122 and second material layers 124 that are alternately stacked. Accordingly, the second material layer 124 may be disposed between a pair of first material layers 122 adjacent to each other, and conversely, the first material layer 122 may be disposed between a pair of second material layers 124 adjacent to each other. In the EUV mask 100 of the present embodiment, each of the first material layers 122 and the second material layers 124 may be stacked in about 40 layers to about 60 layers. However, the number of layers of each of the first material layers 122 and the second material layers 124 is not limited to the above numerical range.

Here, the first material layer 122 may be a low refractive index layer, and the second material layer 124 may be a high refractive index layer. Accordingly, the second material layer 124 may have a higher refractive index than the first material layer 122. For example, the first material layer 122 may include molybdenum (Mo), and the second material layer 124 may include Si. However, the materials of the first material layer 122 and the second material layer 124 are not limited to the above materials. Meanwhile, in the EUV mask 100 of the present embodiment, the first material layer 122, which is the low refractive index layer, may be disposed on the lowermost portion of the reflective layer 120, and the second material layer 124, which is the high refractive index layer, may be disposed on the uppermost portion of the reflective layer 120.

The capping layer 125 may be disposed on the reflective layer 120. The capping layer 125 may limit and/or prevent damage to the reflective layer 120 and surface oxidation of the reflective layer 120. In the EUV mask 100 of the present embodiment, the capping layer 125 may cover the upper surface of the high refractive index layer, for example, the second material layer 124 of Si, to limit and/or prevent the high refractive index layer from being oxidized. For example, the capping layer 125 may include ruthenium (Ru). However, the material of the capping layer 125 is not limited to ruthenium (Ru). The capping layer 125 may be optional. Accordingly, in some embodiments, the capping layer 125 may be omitted.

The absorber layer 130 may be disposed on the capping layer 125. When the capping layer 125 is omitted, the absorber layer 130 may be disposed on the reflective layer 120, for example, the second material layer 124. The absorber layer 130 may include the transfer area (see TA of FIG. 6A) and the light blocking area. As described above with respect to the substrate 110, the absorber patterns (see 132 and 134 of FIG. 6A) and an open area (see 130P in FIG. 6A) to be transferred on the wafer through the exposure process may be disposed in the transfer area TA. However, the EUV mask 100 of the present embodiment is a blank mask, and the absorber patterns and the open area may not be formed in the transfer area TA.

The absorber layer 130 may include a material that absorbs light incident on the absorber layer 130, for example, a EUV ray. Therefore, the EUV ray incident on the absorber layer 130 may not reach the capping layer 125 and/or the reflective layer 120. The absorber layer 130 may include, for example, TaN, TaHf, TaHfN, TaBSi, TaBSiN, TaB, TaBN, TaSi, TaSiN, TaGe, TaGeN, TaZr, TaZrN, or a combination thereof. However, the material of the absorber layer 130 is not limited to the above materials.

For reference, as will be described below with regard to a EUV mask 200 of FIGS. 6A and 6B, the EUV ray incident on the capping layer 125 exposed by the open area 130P of the absorber layer 130 may penetrate the capping layer 125 to reach the reflective layer 120. In addition, the EUV ray may be reflected by the reflective layer 120 and irradiated onto a wafer that is an exposure target. Accordingly, the pattern transferred on the wafer may correspond to the shape of the open area 130P of the absorber layer 130.

As shown in FIG. 1, the absorber layer 130 may include a dummy hole pattern DHP disposed in a rectangular frame shape along an edge portion of the absorber layer 130. A plurality of dummy holes DH exposing the capping layer 125 may be formed in the dummy hole pattern DHP. When the capping layer 125 is omitted, the dummy holes DH may expose the reflective layer 120, e.g., the second material layer 124.

A second width W2 of the dummy hole pattern DHP may be, for example, equal to or greater than 1.0 mm. Here, the second width W2 may be defined as a direction perpendicular to s direction in which the dummy hole pattern DHP extends. For example, in FIG. 1, in the case of the dummy hole patterns DHPs on the upper and lower sides extending in the first direction (X direction), the second width W2 may be defined in the second direction (Y direction), and in the case of the dummy hole patterns DHP on the left and right sides extending in the second direction (Y direction), the second width W2 may be defined in the first direction (X direction).

A horizontal cross-section of the dummy hole DH in the dummy hole pattern DHP may have various shapes. For example, in the EUV mask 100 of the present embodiment, the horizontal cross-section of the dummy hole DH may be a rectangle. However, the horizontal cross-section of the dummy hole DH is not limited to the rectangle. For example, according to an embodiment, the horizontal cross-section of the dummy hole DH may have various shapes, such as a circle, an ellipse, and a polygon other than the rectangle.

As may be seen from FIGS. 2A to 2C, the size of the dummy hole DH disposed in the dummy hole pattern DHP may be very small. Here, the size of the dummy hole DH may be defined as a width, a diameter, a short axis, etc. In other words, when the horizontal cross-section of the dummy hole DH is the polygon, the size of the dummy hole DH may be defined as a width between opposite sides. Also, when the horizontal cross-section of the dummy hole DH is the circle, the size of the dummy hole DH may be defined as a diameter. Meanwhile, when the horizontal cross-section of the dummy hole DH is the ellipse, the size of the dummy hole DH may be defined as a minor axis. However, the size of the dummy hole DH is not limited to the above definitions. For example, according to an embodiment, the size of the dummy hole DH may be defined in various ways.

The size of the dummy hole DH may be, for example, equal to or smaller than 1 μm. More specifically, in the EUV mask 100 of the present embodiment, the horizontal cross-section of the dummy hole DH may have a rectangular shape, and a third width W3 of the dummy hole DH may be equal to or less than 1 μm. However, the third width W3 of the dummy hole DH is not limited to the above numerical range.

The dummy hole DH may be disposed in a two-dimensional array structure in the dummy hole pattern DHP. In other words, the dummy holes DH may be arranged at regular intervals or pitches in the first direction (X direction) and the second direction (Y direction) in the dummy hole pattern DHP. For example, the dummy holes DH adjacent to each other in the first direction (X direction) or the second direction (Y direction) may have a first distance S equal to or less than 4 μm. Further, when it is assumed that the dummy holes DH have a width equal to or less than 1 μm, the dummy holes DH may have a first pitch P equal to or less than 5 μm in the first direction (X direction) or the second direction (Y direction). However, the first space S or the first pitch P of the dummy holes DH is not limited to the above numerical ranges.

Meanwhile, when the second width W2 of the dummy hole pattern DHP is about 2 mm and the dummy holes DH have a pitch of about 5 μm, about 400 dummy holes DH may be disposed in a direction of the second width W2 in the dummy hole pattern DHP. However, the second width W2 of the dummy hole pattern DHP and the third width W3 of the dummy hole DH, space, or pitch may be variously changed, the number of dummy holes DH disposed in the dummy hole pattern DHP in the direction of the second width W2 is not limited to the above numerical value.

In the EUV mask 100 of the present embodiment, the dummy holes DH of the dummy hole pattern DHP may be disposed to limit and/or prevent a blister defect from occurring in a EUV exposure process. Here, the blister defect may refer to a defect in which a gap between the capping layer 125 and the reflective layer 120 or between the absorber layer 130 and the reflective layer 120 swells. More specifically, impurities, for example, carbon-containing impurities, may be formed on the surface of the EUV mask during the EUV exposure process. Hydrogen elements may be supplied on the EUV mask to remove these impurities. Hydrogen elements may penetrate into the EUV mask and penetrate between the capping layer 125 and the reflective layer 120 or between the absorber layer 130 and the reflective layer 120. Therefore, hydrogen atoms may be accumulated between the capping layer 125 and the reflective layer 120 or between the absorber layer 130 and the reflective layer 120, and the blister defect may occur in which the gap between the capping layer 125 and the reflective layer 120 or between the absorber layer 130 and the reflective layer 120 swells due to the accumulated hydrogen atoms. In the EUV mask 100 of the present embodiment, the dummy holes DH are formed in the dummy hole pattern DHP and hydrogen atoms are discharged through the dummy holes DH, and thus, the blister defect may be effectively limited and/or prevented. Accordingly, reliability and durability of the EUV mask 100 may be greatly improved.

Meanwhile, patterns or holes to limit and/or prevent the blister defect may also be formed in a portion of the absorber layer 130 inside the dummy hole pattern DHP. Such patterns or holes are referred to as anti-blister patterns (ABPs) or anti-blister pattern holes (ABPHs). However, because the EUV mask 100 of the present embodiment is a blank mask, the ABP or the ABPH has not yet been formed. Herein, the ABPH refers to a hole formed in the absorber layer 130, and the ABP refers to a pattern formed through the ABPH, but hereinafter, the ABPH and the ABP are collectively referred to as the ABP, except when it is necessary to clearly distinguish the ABPH and the ABP.

In the EUV mask 100 of the present embodiment, the dummy holes DH of the dummy hole pattern DHP are formed through a photo process, but the ABP may be formed through an electron beam exposure process. In other words, the ABP may be formed using an electron beam exposure apparatus in a process of forming an absorber pattern on the absorber layer 130 through the electron beam exposure apparatus. Meanwhile, the ABP may not be transferred to a wafer in the subsequent EUV exposure process using the EUV mask. Accordingly, the width or diameter of the ABPH may be less than the minimum line width determined by the resolution of a EUV exposure apparatus.

In contrast, in the EUV mask 100 of the present embodiment, because the dummy hole pattern DHP is not the transfer area TA, the size of the dummy hole DH of the dummy hole pattern DHP may not be affected by the resolution of the EUV exposure apparatus. However, the dummy hole pattern DHP may include a ground area 130A to which the electron beam exposure apparatus is grounded, and in order to limit and/or minimize a change in the contact resistance of the ground area 130A, the dummy hole DH may be formed in a small size as much as possible.

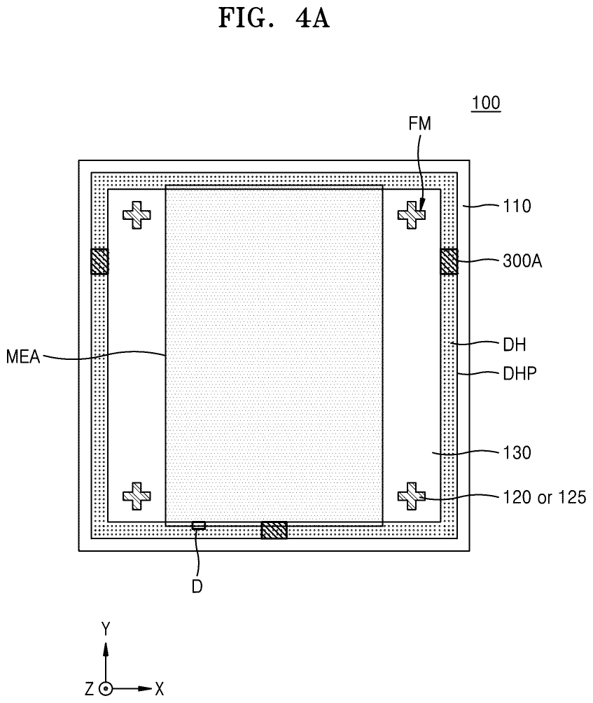

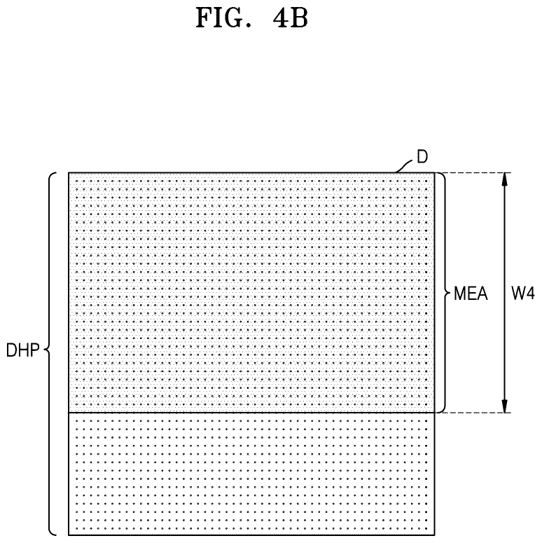

More specifically, the EUV mask 100 of the present embodiment is a blank mask, and therefore, the absorber pattern 130 is formed on a main exposure area (see MEA of FIG. 4A) of the absorber layer 130 through an electron beam exposure apparatus later, and thus, a final EUV mask (see 200 in FIG. 6A) may be completed. When the absorber pattern 130 is formed on the main exposure area using the electron beam exposure apparatus, based on the operation principle of the electron beam exposure process, the electron beam exposure apparatus needs to be grounded to a partial area of the EUV mask 100. In FIG. 1, the ground area 300A to which the electron beam exposure apparatus is grounded is hatched on the outer portion of the EUV mask 100. The ground area 300A may be included in the dummy hole pattern DHP. In FIG. 1, the ground areas 300A are indicated by two left and right sides and one lower side of the dummy hole pattern DHP, but according to an embodiment, the ground areas 300A may be disposed at a different location and in a different number on the outer portion of the EUV mask 100.

In the EUV mask 100 of the present embodiment, a plurality of dummy holes DH may be formed in the dummy hole pattern DHP, and the dummy holes DH may also be formed in the ground area 300A. Meanwhile, the ground area 300A needs to have low contact resistance in order to perform a smooth electron beam exposure process. However, because the dummy holes DH correspond to a kind of empty space, the dummy holes DH may increase the contact resistance of the ground area 300A. Therefore, in the EUV mask 100 of the present embodiment, in order to limit and/or minimize the increase in the contact resistance of the ground area 300A, the dummy holes DH may be formed to a small size. For example, the dummy holes DH may be formed such that the area ratio of the dummy holes DH in the ground area 300A to the area of the ground area 300A is equal to or less than 50% or equal to or less than 30%. Meanwhile, because the dummy holes DH are disposed at a uniform density in the dummy hole pattern DHP, the dummy holes DH may be formed such that the area ratio of the entire dummy holes DH to the area of the dummy hole pattern DHP is equal to or less than 50% or equal to or less than 30%.

As described above, the ground area 300A may be included in the dummy hole pattern DHP. Also, the width of the ground area 300A in the first direction (X direction) may be substantially the same as to or less than the width of the dummy hole pattern DHP. Meanwhile, as may be seen through the cross-sectional view of FIG. 3B, the ground pin 300 of the electron beam exposure apparatus may contact the ground area 300A. Also, as may be seen from the enlarged cross-sectional view of FIG. 3C, a plurality of dummy holes DH may be disposed in the dummy hole pattern DHP or the ground area 300A in the first direction (X direction). In addition, as described above with respect to the second width W2 of the dummy hole pattern DHP, the size and space of the dummy holes DH, etc., about 400 dummy holes DH may be disposed in the dummy hole pattern DHP in the first direction (X direction). However, for convenience of illustration, only a few dummy holes DH are shown in FIG. 3C.

In the EUV mask 100 of the present embodiment, the dummy holes DH of the dummy hole pattern DHP may be formed through a general photo process. This is because the electron beam exposure process may not be performed on the ground area 300A. Also, the location of the ground area 300A may be changed without being fixed. This may be caused by the rotation of the EUV mask in mask defect avoidance (MDA), etc. After a process of forming a fiducial mark (FM) on the EUV mask 100, the MDA may mean a process of inspecting whether a defect exists on the EUV mask 100, and, when there is the defect, avoiding the defect from appearing by linearly moving or rotating the EUV mask 100 so that the defect is located in the portion where the absorber layer 130 exists. For reference, because the absorber layer 130 is a portion where the EUV ray is absorbed, the defect of the absorber layer 130 may not be transferred to the wafer in the EUV exposure process, and therefore, the occurrence of the defect may be avoided by moving the defect to the absorber layer 130. As a result, in the electron beam exposure process of forming the absorber pattern on the main exposure area MEA of the absorber layer 130, even when the location of the ground area 300A is initially set, because the location of the ground area 300A may be changed after the MDA, the location of the ground area 300A may be changed without being fixed.

Meanwhile, the ground area 300A is still located on the outer portion of the EUV mask 100 even when the location of the ground area 300A is changed after the MDA. Therefore, in the EUV mask 100 of the present embodiment, the entire outer portion of the EUV mask 100 where the ground area 300A may be located is defined as the dummy hole pattern DHP, and the dummy holes DH may be formed in the dummy hole pattern DHP. For example, in the EUV mask 100 of the present embodiment, the dummy hole pattern DHP may be defined in the rectangular frame shape along the edge portion of the absorber layer 130 as shown in FIG. 1.

For reference, the FM may be used to detect a defect in the MDA. For example, in FIG. 1, cross-shaped patterns disposed at four vertices of a quadrangle may correspond to FMs. The FM may be generally formed through a photolithography process. That is, the FM may be formed by forming a hole corresponding to the shape of the FM in the absorber layer 130. In other words, the capping layer 125 or the reflective layer 120 on the lower portion may be exposed through the FM.

The EUV mask 100 of the present embodiment may include the dummy hole pattern DHP defined in the rectangular frame shape along the edge portion of the absorber layer 130. In addition, a plurality of fine dummy holes DH may be disposed in the dummy hole pattern DHP. Accordingly, in the EUV mask 100 of the present embodiment, because hydrogen atoms are discharged through the dummy holes DH in the EUV exposure process, the blister defect may be effectively limited and/or prevented. As a result, the EUV mask 100 of the present embodiment may implement a EUV mask with improved reliability and durability.

In addition, in the case of a EUV mask of comparative example in which a dummy hole pattern is not formed on the edge portion of an absorber layer, in the EUV exposure process, when the EUV mask is exposed at 110 kJ/cm² or more, the blister defect may occur in an area where the ABP is not disposed, that is, the edge area of the absorber layer, and thus, the yield of a wafer may decrease. On the other hand, in the case of the EUV mask 100 of the present embodiment, in order to limit and/or prevent the blister defect caused by hydrogen in the ground area 130A where ABP formation through the electron beam exposure apparatus is impossible, the dummy hole pattern DHP including the plurality of dummy holes DH may be disposed in the rectangular frame shape along the edge portion of the absorber layer 130. Accordingly, the lifetime of the EUV mask may be greatly extended. In addition, the dummy holes DH may be formed in the ground area 130A or the dummy hole pattern DHP at an area ratio to the extent that there is little change in the contact resistance of the ground area 130A, for example, equal to or less than 30%, or equal to or less than 10%, and thus, the electron beam exposure apparatus may be used smoothly without an occurrence of a positional error. Furthermore, because the dummy hole pattern DHP is disposed at the edge portion of the EUV mask 100 corresponding to the light blocking area, the size of the dummy holes DH may be formed regardless of the resolution of the EUV exposure apparatus, and, may be formed through a general photolithography device that does not require grounding. Meanwhile, because the dummy hole pattern DHP has the rectangular frame shape, the dummy holes DH may be disposed in the ground area 300A regardless of rotation in the MDA. Finally, the dummy holes DH of the dummy hole pattern DHP may be manufactured simultaneously with the manufacture of the FM or another main process mark or key, and accordingly, a turn around time (TAT) loss with respect to the manufacture of the EUV mask 100 which is the blank mask may be limited and/or minimized

FIG. 4A is a plan view of a EUV mask according to an embodiment. FIG. 4B is a plan view showing an enlarged portion D of the EUV mask of FIG. 4A with respect to the positional relationship between the main exposure area MEA by an electron beam and the dummy hole pattern DHP. The descriptions already given with reference to FIGS. 1 to 3C are briefly provided or omitted.

Referring to FIGS. 4A and 4B, in the EUV mask 100 of the present embodiment, the main exposure area MEA may be defined at a central portion of the absorber layer 130 in the first direction (X direction). In addition, the main exposure area MEA may extend to the upper and lower edge portions of the absorber layer 130 in the second direction (Y direction). The main exposure area MEA may refer to an area where an absorber pattern is formed on the absorber layer 130 by an electron beam exposure apparatus. Meanwhile, the outside of the main exposure area MEA may correspond to a sub-exposure area of the absorber layer 130. Although no absorber pattern is formed in the sub-exposure area, an ABP may be formed by an electron beam exposure apparatus. The ABP may also be formed in the main exposure area MEA by the electron beam exposure apparatus.

Meanwhile, the ground area 300A may be excluded from the sub-exposure area. This is because the ABP may not be formed in the ground area 300A by the electron beam exposure apparatus. In addition, in the case of the EUV mask 100 of the present embodiment, because the dummy hole pattern DHP is separately formed in a rectangular frame shape along the edge of the absorber layer 130, the dummy hole pattern DHP may also be excluded from the sub-exposure area.

In the EUV mask 100 of the present embodiment, the dummy hole pattern DHP may at least partially overlap the main exposure area MEA. In other words, the main exposure area MEA may extend in the second direction (Y direction) to partially overlap the upper and lower sides of the dummy hole pattern DHP in the second direction (Y direction). As may be seen from FIG. 4B, an overlapping part of the dummy hole pattern DHP and the main exposure area MEA may have a fourth width W4 in the second direction (Y direction). The fourth width W4 of the overlapping part may be, for example, equal to or greater than 0.05 mm. However, the fourth width W4 of the overlapping part is not limited to the above numerical range.

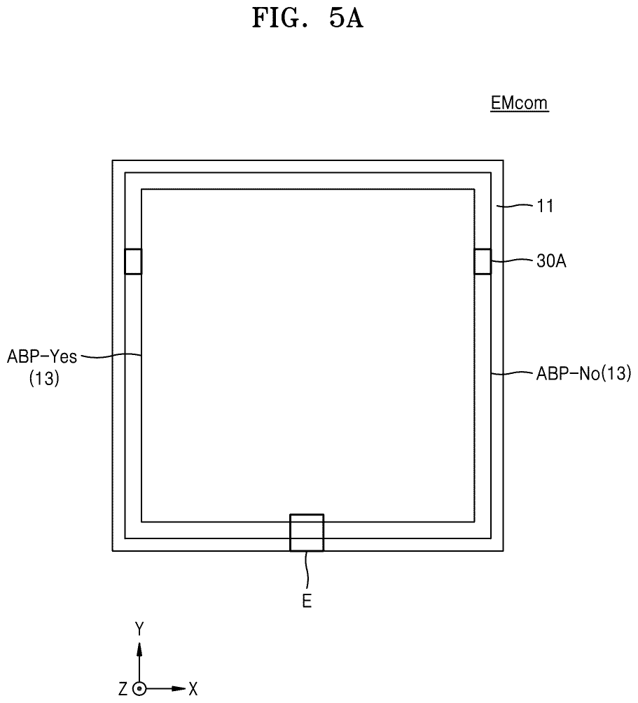

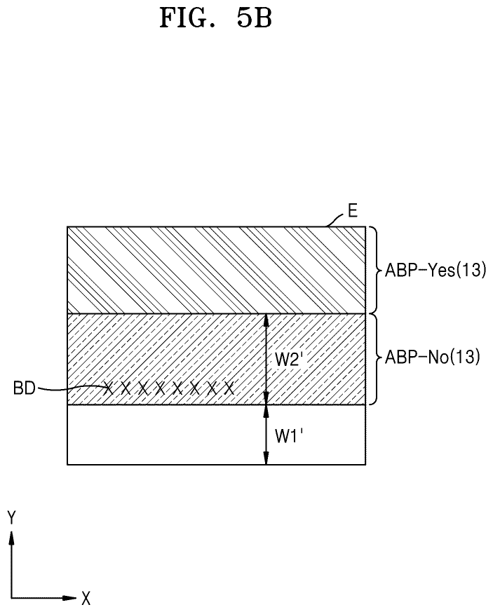

FIG. 5A is a plan view of a EUV mask according to a comparative example. FIG. 5B is a plan view showing an enlarged portion E of the EUV mask of FIG. 5A.

Referring to FIGS. 5A and 5B, in the case of a EUV mask EMcom of the comparative example, a dummy hole pattern may not be formed. Meanwhile, the EUV mask EMcom of the comparative example is also a blank mask, and a ground area 30A may be disposed on an outer portion of the absorber layer 13. Meanwhile, the absorber layer 13 may be classified into an ABP available area ABP-Yes and an ABP unavailable area ABP-No. The ABP available area ABP-Yes may correspond to an area in which an ABP may be formed through the electron beam exposure apparatus. In contrast, the ABP unavailable area ABP-No is an area including the ground area 30A and may correspond to an area in which an ABP may not be formed. Meanwhile, the ABP may be actually formed in the ABP unavailable area ABP-No, except for only the ground area 30A. However, as described above, the position of the ground area 30A may not be accurately set due to a MDA, and therefore, the entire area in the rectangular frame shape may be set as the ABP unavailable area ABP-No generally along the edge of the absorber layer 13.

In the EUV mask EMcom of the comparative example, the ABP may be formed in the ABP available area ABP-Yes through an electron beam exposure process. More specifically, in the ABP available area ABP-Yes of the absorber layer 13, the ABP may be formed in the absorber pattern of the absorber layer 13, and because a capping layer or a reflective layer is exposed in the open area of the absorber layer 13, the ABP is not formed in the open area of the absorber layer 13.

In the EUV mask EMcom of the comparative example, the ABP may not be formed in the ABP unavailable area ABP-No in the rectangular frame shape. Accordingly, as may be seen through the enlarged view of FIG. 5B, in the EUV exposure process, a blister defect BD may occur in the ABP unavailable area ABP-No. In the enlarged view of FIG. 5B, an unhatched portion may correspond to an exposed portion of the substrate 11. The exposed portion of the substrate 11 may have a first width W1′ in the second direction (Y direction). The first width W1′ may be substantially the same as the first width W1 of the exposed portion of the substrate 110 of the EUV mask 100 of FIG. 1. However, according to an embodiment, the first width W1′ of the exposed portion of the substrate 11 of the EUV mask EMcom and the first width W1 of the exposed portion of the substrate 110 of the EUV mask 100 may be different from each other.

Meanwhile, the ABP unavailable area ABP-No and the ABP available area ABP-Yes of the absorber layer 13 may be sequentially disposed in the second direction (Y direction). In addition, the ABP unavailable area ABP-No may have a second width W2′ in the second direction (Y direction). The second width W2′ may be substantially the same as the second width W2 of the dummy hole pattern DHP of the absorber layer 130 of the EUV mask 100 of FIG. 1. However, according to an embodiment, the second width W2′ of the ABP unavailable area ABP-No of the absorber layer 13 of the EUV mask EMcom and the second width W2 of the dummy hole pattern DHP of the absorber layer 130 of the EUV mask 100 may be different from each other.

FIG. 6A is a plan view of a EUV mask according to an embodiment. FIG. 6B is a cross-sectional view showing taken along line II-II′ of FIG. 6A. FIGS. 6A and 6B are described with reference to FIGS. 1 to 3A together, and the descriptions already given with reference to FIGS. 1 to 5B are briefly provided or omitted.

Referring to FIGS. 6A and 6B, a EUV mask 200 of the present embodiment may be different from the EUV mask 100 of FIG. 1 in that absorber patterns 132 and 134 are formed in the main exposure area MEA of the absorber layer 130 by an electron beam exposure apparatus. In other words, the EUV mask 100 of FIG. 1 is a blank mask in which no absorber pattern is formed on the absorber layer 130, but the EUV mask 200 of the present embodiment may correspond to a completed EUV mask that may be used in an EUV process while the absorber patterns 132 and 134 are formed on the absorber layer 130.

As described above, the absorber layer 130 may include the transfer area TA and a light blocking area outside the transfer area TA. For reference, as shown in FIG. 6A, the transfer area TA may be defined inside the main exposure area MEA. According to an embodiment, the transfer area TA may be substantially the same as the main exposure area MEA. However, because the main exposure area MEA partially overlaps the dummy hole pattern DHP, when the dummy hole DH of the dummy hole pattern DHP has a size equal to or greater than the resolution of an EUV exposure apparatus, a portion of the dummy hole DH needs not to be transferred, and thus, the transfer area TA may be defined smaller than the main exposure area MEA so as not to overlap with the dummy hole pattern DHP.

In the transfer area TA, the first and second absorber patterns 132 and 134 disposed on the capping layer 125 and an open area 130P between the first and second absorber patterns 132 and 134 may be disposed. The open area 130P may include first to fourth open areas 130P1 to 130P4 defined by the first and second absorber patterns 132 and 134. Meanwhile, the absorber patterns 132 and 134 in the transfer area TA of FIG. 6A are for illustrative purposes only, and are exaggeratedly indicated. Absorber patterns in the transfer area TA may be actually have minute and various shapes.

Due to the material of the absorber layer 130, the first and second absorber patterns 132 and 134 of the absorber layer 130 may absorb light incident to the first and second absorber patterns 132 and 134, that is, a EUV ray. In addition, the EUV ray incident on the capping layer 125 exposed by the open area 130P of the absorber layer 130 may penetrate the capping layer 125 and reach the reflective layer 120. The EUV ray reaching the reflective layer 120 may be reflected by the reflective layer 120 and irradiated onto a wafer that is an exposure target. Accordingly, the pattern transferred on the wafer may correspond to the shape of the open area 130P of the absorber layer 130.

Meanwhile, in the EUV mask 200 of the present embodiment, an ABP may be formed on each of the first and second absorber patterns 132 and 134 of the transfer area TA. An ABPH may have a size less than the resolution of the EUV exposure apparatus. Accordingly, the ABP may not be transferred to the wafer in the EUV exposure process. In other words, the entire shape of each of the first and second absorber patterns 132 and 134 including the ABP are transferred to the wafer, and the fine shape of the ABP is not transferred to the wafer.

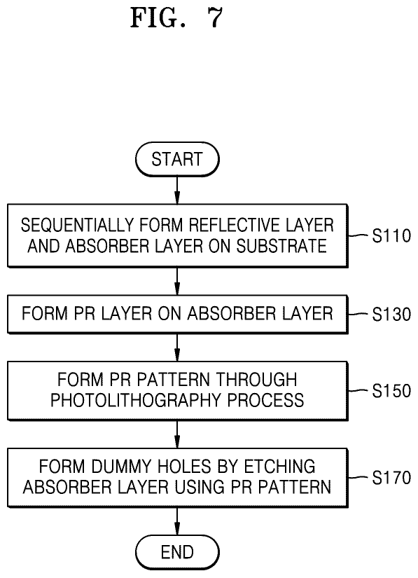

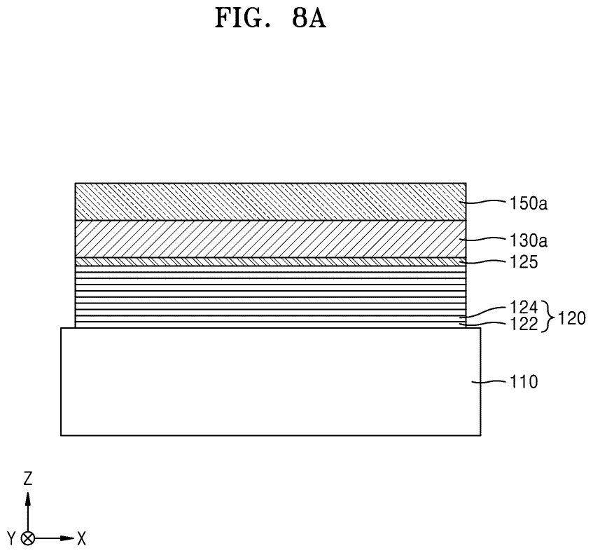

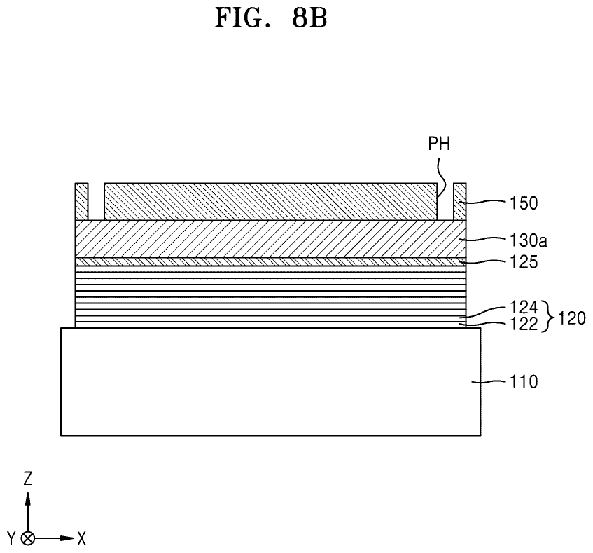

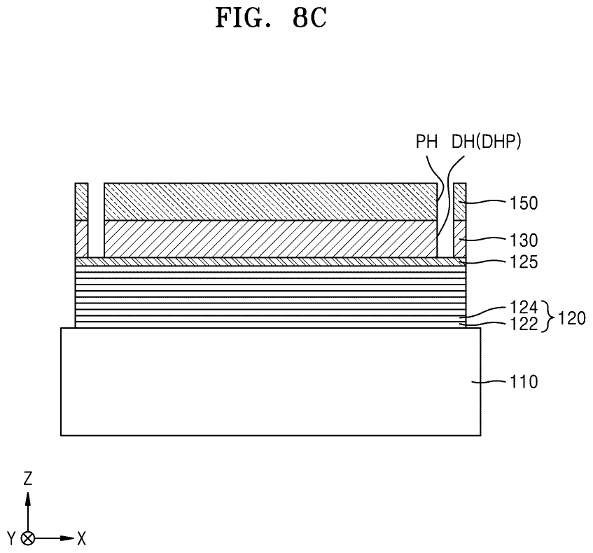

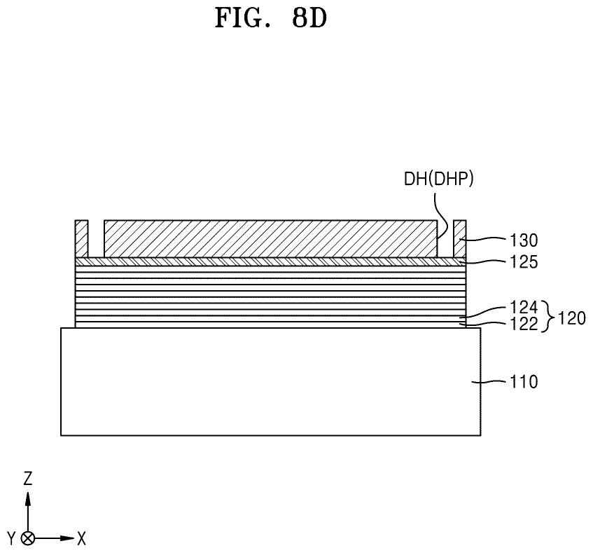

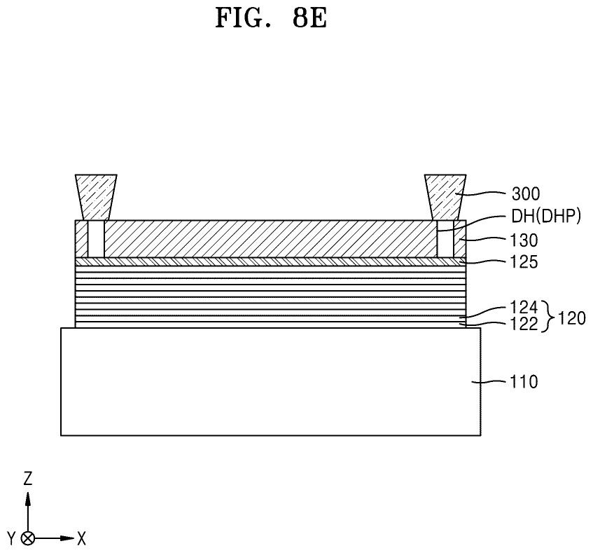

FIG. 7 is a flowchart schematically illustrating a process of a manufacturing method of a EUV mask according to an embodiment. FIGS. 8A to 8E are cross-sectional views of the EUV mask corresponding to operations of the manufacturing method of the EUV mask of FIG. 7. FIGS. 8A to 8E may correspond to cross-sectional views of FIG. 3A or 3B. FIGS. 7 to 8E are described with reference to FIGS. 1, and 3A to 3C together, and the descriptions already given with reference to FIGS. 1 to 6B are briefly provided or omitted.

Referring to FIGS. 7 and 8A, in the EUV mask manufacturing method of the present embodiment, first, the reflective layer 120 and the absorber layer 130a are sequentially formed on the substrate 110 (S110). The substrate 110 may include an LTEM. For example, the substrate 110 may include glass, silicon (Si), quartz, etc. However, the material of the substrate 110 is not limited to the above materials.

The reflective layer 120 may be disposed on the substrate 110 and may have a structure in which two material layers 122 and 124 are alternately stacked in several tens of layers. For example, the reflective layer 120 may include the first material layers 122 and the second material layers 124 that are alternately stacked, and each of the first material layers 122 and the second material layers 124 may be stacked in about 40 layers to about 60 layers. However, the number of layers of each of the first material layers 122 and the second material layers 124 is not limited to the above numerical range. In the EUV mask manufacturing method of the present embodiment, the first material layer 122 may include Mo having a low refractive index, and the second material layer 124 may include Si having a high refractive index. However, the materials of the first material layer 122 and the second material layer 124 are not limited to Mo and Si.

Meanwhile, the capping layer 125 may be formed on the reflective layer 120 before the absorber layer 130a is formed. For reference, the second material layer 124 may be disposed on the uppermost layer of the reflective layer 120, and the capping layer 125 may be formed on the second material layer 124. The capping layer 125 may include, for example, Ru. However, the material of the capping layer 125 is not limited to Ru. Also, according to an embodiment, the capping layer 125 may be omitted.

After the capping layer 125 is formed, the absorber layer 130a may be formed on the capping layer 125. When the capping layer 125 is omitted, the absorber layer 130a may be formed on the reflective layer 120. The absorber layer 130a may include a material that absorbs light incident on the absorber layer 130a, for example, a EUV ray. The absorber layer 130a may include, for example, TaN, TaHf, TaHfN, TaBSi, TaBSiN, TaB, TaBN, TaSi, TaSiN, TaGe, TaGeN, TaZr, TaZrN, or a combination thereof. However, the material of the absorber layer 130a is not limited to the above materials.

Subsequently, a photoresist (PR) layer 150a is formed on the absorber layer 130a (S130). The PR layer 150a may include an appropriate material in consideration of a type of a light source used in a photolithography process, a develop process, an etching selectivity with the absorber layer 130a, etc.

Referring to FIGS. 7 and 8B, the photolithography process is performed on the PR layer 150a to form a PR pattern 150. The photolithography process may include an exposure process, a bake process, the develop process, etc. Meanwhile, for convenience of explanation, the dummy hole pattern DHP may be represented by one dummy hole DH. Accordingly, in FIG. 8B, one PR hole PH corresponding to one dummy hole pattern DHP may be formed in the PR pattern 150. However, in reality, the dummy hole pattern DHP may include a plurality of dummy holes DH, and therefore, to form the plurality of dummy holes DH, a plurality of fine PR holes PH may be formed in the PR pattern 150. Meanwhile, in FIG. 8B, the PR holes PH may be formed in both sides of the first direction (X direction). These two PR holes PH may correspond to two dummy hole pattern DHP, and two dummy hole patterns DHP may correspond to the two ground areas 300A.

Referring to FIGS. 7, 8C, and 8D, after the PR pattern 150 is formed, the dummy holes DH are formed by etching the absorber layer 130a using the PR pattern 150 as an etch mask (S170). As shown in FIG. 1, the dummy holes DH may be formed in the dummy hole pattern DHP in a rectangular frame shape along the edge of the absorber layer 130. In addition, a plurality of dummy holes DH may be formed in the dummy hole pattern DHP. However, in the case of FIG. 8C, as described above, the dummy hole pattern DHP is represented by one dummy hole DH. However, in reality, as shown in FIGS. 3A and 3C, a plurality of dummy holes DH may be formed in the dummy hole pattern DHP. In addition, dummy hole patterns DHP may be formed on both sides of the absorber layer 130 in the first direction (X direction), and each of these two dummy hole patterns DHP may correspond to the ground area 130A.

Meanwhile, as shown in FIG. 8D, after the dummy holes DH are formed in the dummy hole pattern DHP, the PR pattern 150 may be removed through an ashing and/or stripping process. After removal of the PR pattern 150, the EUV mask 100 substantially the same as that of FIG. 3A may be manufactured. Here, the EUV mask 100 may be a blank mask.

Referring to FIG. 8E, after the EUV mask 100 is manufactured through the formation of the dummy holes DH, the EUV mask 100 may be injected into an electron beam exposure apparatus so as to form an absorber pattern on the main exposure area MEA of the absorber layer 130. In this case, the ground pin 300 of the electron beam exposure apparatus may contact the ground area 300A of the dummy hole pattern DHP.

Meanwhile, although not shown in FIGS. 8A to 8E, the formation of the dummy holes DH in the dummy hole pattern DHP may be formed simultaneously with the formation of a FM or another main process mark or key. In other words, when the PR pattern 150 is formed in FIG. 8B, along with the PR hole PH corresponding to the dummy hole DH in the PR pattern 150, pattern holes corresponding to the FM or the other main process key may be formed. Thereafter, the FM or the other main process key may be formed along with the dummy hole DH by etching the absorber layer 130 using the PR pattern 150 as an etch mask.

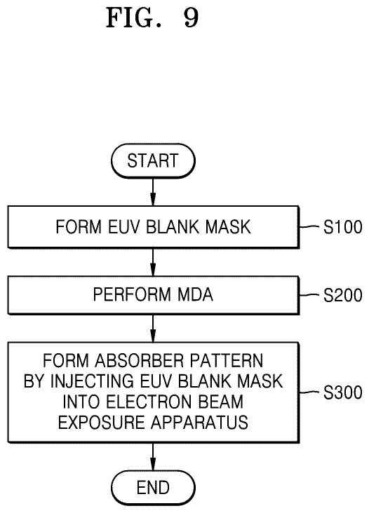

FIG. 9 is a flowchart schematically illustrating a process of a manufacturing method of a EUV mask according to an embodiment. FIG. 9 is described with reference to FIGS. 7 to 8E, and the descriptions already given with reference to FIGS. 7 to 8E are briefly provided or omitted.

Referring to FIG. 9, in the EUV mask manufacturing method of the present embodiment, first, a EUV blank mask is formed (S100). Here, the EUV blank mask may be the EUV mask 100 of FIG. 1. Accordingly, in the EUV blank mask, the dummy hole pattern DHP in a rectangular frame shape may be formed along the edge of the absorber layer 130, and a plurality of dummy holes DH may be formed in the dummy hole pattern DHP. Meanwhile, only a FM or another main process key are formed in the absorber layer 130 inside the dummy hole pattern DHP, and a separate absorber pattern may not be formed. A process of forming the EUV blank mask has been described with reference to FIGS. 7 to 8E, and thus, a detailed description thereof is omitted.

After the EUV blank mask is formed, a MDA is performed (S200). After a process of forming the FM and the other main process key on the EUV blank mask, The MDA may mean process of inspecting whether a defect exists on the EUV blank mask, and, when there is the defect, avoiding the defect from appearing by linearly moving or rotating the EUV blank mask so that the defect is located in the portion where the absorber layer 130 exists. For reference, because the absorber layer 130 is a portion where the EUV ray is absorbed, the defect of the absorber layer 130 may not be transferred to the wafer in the EUV exposure process, and therefore, the occurrence of the defect may be avoided by moving the defect to the absorber layer 130. Meanwhile, the location of the ground area 300A is changed through the MDA as described above.

Thereafter, an absorber pattern is formed on the main exposure area MEA of the absorber layer 130 by injecting the EUV blank mask into an electron beam exposure apparatus (S300). When the absorber pattern is formed through the electron beam exposure apparatus, as shown in FIG. 8E, the pin 300 of the electron beam exposure apparatus may contact the ground area 300A of the dummy hole pattern DHP of the absorber layer 130. The EUV mask 200 of FIG. 6A used in the EUV exposure process may be completed by forming the absorber pattern on the main exposure area MEA of the absorber layer 130.

In addition, in the process of forming the absorber pattern on the main exposure area MEA using the electron beam exposure apparatus, an ABP may be formed on the main exposure area MEA. In addition, the ABP may also be formed in a sub-exposure area outside the main exposure area MEA.

While inventive concepts have been particularly shown and described with reference to embodiments thereof, it will be understood that various changes in form and details may be made therein without departing from the spirit and scope of the following claims.

1. An extreme ultraviolet (EUV) mask comprising:
a substrate having a rectangular shape;
a reflective layer on the substrate and having a rectangular shape smaller than the rectangular shape of the substrate; and
an absorber layer on the reflective layer, the absorber layer having a same shape as the rectangular shape of the reflective layer, and the absorber layer including a dummy hole pattern, wherein
the dummy hole pattern is in a rectangular frame shape along an edge portion of the absorber layer,
the dummy hole pattern includes a plurality of dummy holes, and
the plurality of dummy holes expose the reflective layer.

2. The EUV mask claim 1, wherein
the dummy hole pattern includes a ground area where an electron beam exposure apparatus is grounded thereon when an absorber pattern is formed on the absorber layer by the electron beam exposure apparatus.

3. The EUV mask of claim 1, wherein
the plurality of dummy holes are arranged in a two-dimensional array in the dummy hole pattern, and
an area ratio of all of the plurality of dummy holes to an area of the dummy hole pattern is equal to or less than 30%.

4. The EUV mask of claim 1, wherein
the absorber layer is divided into a main exposure area and a sub-exposure area outside the main exposure area,
the main exposure area is at a central portion of the absorber layer in a first direction,
the main exposure area extends in a second direction,
the second direction is perpendicular to the first direction,
the main exposure area and the dummy hole pattern at least partially overlap at both ends thereof in the second direction.

5. The EUV mask of claim 1, wherein
the reflective layer exposes an exposed portion of the substrate,
the exposed portion of the substrate has an exposed upper surface in a rectangular frame shape at an outer portion of the substrate, and
the dummy hole pattern is adjacent to the exposed portion of the substrate and surrounded by the exposed portion of the substrate in a plan view.

6. The EUV mask of claim 1, further comprising:
a capping layer on the reflective layer,
wherein the plurality of dummy holes expose the capping layer.

7. The EUV mask of claim 1, wherein
the substrate includes a low thermal expansion material (LTEM) or quartz,
the reflective layer has a multilayer structure in which two material layers are alternately stacked, and
the absorber layer includes a material that absorbs a EUV ray.

8. The EUV mask of claim 1, wherein
the dummy hole pattern is an area that is not used in a EUV exposure process, and
a size of the plurality of dummy holes is not affected by a resolution of the EUV exposure process.

9. The EUV mask of claim 1, wherein
the dummy hole pattern has an upper side, a lower side, a left side, and a right side,
the upper side and the lower side of the dummy hole pattern extend in a first direction,
the left side and the right side of the dummy hole pattern extend in a second direction,
the second direction is perpendicular to the first direction,
widths of the upper side and lower side in the second direction and widths of the left side and the right side in the first direction are each equal to or greater than 1.0 mm,
widths of the plurality of dummy holes are equal to or less than 1.0 mm, and
a distance between two dummy holes adjacent to each other in the first direction or the second direction is equal to or less than 4 mm.

10. The EUV mask of claim 1, wherein
the absorber layer includes fiducial marks at vertex portions of a rectangle.

11. An extreme ultraviolet (EUV) mask comprising:
a substrate having a rectangular shape;
a reflective layer on the substrate and having a rectangular shape smaller than the rectangular shape of the substrate; and
an absorber layer on the reflective layer, the absorber layer having a same shape as the rectangular shape of the reflective layer, and the absorber layer including a transfer area and a dummy hole pattern, wherein
the transfer area includes an absorber pattern for a EUV process in a central portion of the absorber layer in a first direction, the absorber pattern exposes the reflection layer,
the dummy hole pattern is in a rectangular frame shape along an edge portion of the absorber layer, and
the dummy hole pattern includes a plurality of dummy holes, and
the plurality of dummy holes expose the reflective layer.

12. The EUV mask of claim 11, wherein the dummy hole pattern includes a ground area where an electron beam exposure apparatus is grounded thereon when an absorber pattern is formed on the absorber layer by the electron beam exposure apparatus.

13. The EUV mask of claim 11, wherein the plurality of dummy holes are arranged in a two-dimensional array in the dummy hole pattern, and an area ratio of all of the plurality of dummy holes to an area of the dummy hole pattern is equal to or less than 50%.

14. The EUV mask of claim 11, wherein
the absorber layer is divided into a main exposure area and a sub-exposure area outside the main exposure area,
the main exposure area is at a central portion of the absorber layer in a first direction,
and the main exposure area extends in a second direction, the second direction is perpendicular to the first direction,
the transfer area is a same shape as the main exposure area, and
the main exposure area and the dummy hole pattern at least partially overlap at both ends in the second direction.

15. The EUV mask of claim 14, wherein
the absorber layer further includes an anti-blister pattern (ABP) on the main exposure area and the sub-exposure area except for the dummy hole pattern, and
the absorber layer further includes fiducial marks formed in the sub-exposure area at vertex portions of a rectangle.

16. The EUV mask of claim 11, further comprising:
a capping layer on the reflective layer, wherein
the plurality of dummy holes expose the capping layer,
the substrate includes a low thermal expansion material (LTEM) or quartz,
the reflective layer has a multilayer structure in which two material layers are alternately stacked, and
the absorber layer includes a material that absorbs a EUV ray.

17. The EUV mask of claim 11, wherein
the dummy hole pattern is an area that is not used in a EUV exposure process, and
a size of the plurality of dummy holes is not affected by a resolution of the EUV exposure process.

18. The EUV mask of claim 11, wherein the EUV mask is configured to transfer a shape corresponding to the absorber pattern to a wafer in a EUV exposure process.

19.-27. (canceled)
